(19) United States
(12) Patent Application Publication
(10) Pub. No.: US 2014/0264568 A1
(43) Pub. Date: Sep. 18, 2014

(54) SEMICONDUCTOR DEVICE AND METHODS OF MANUFACTURING THE SAME

(71) Applicant: Samsung Electronics Co., Ltd., Suwon-si (KR)

(72) Inventors: Jun-Soo KIM, Anyang-si (KR); Jong-Un KIM, Seoul (KR); Nam-Ho JEON, Hwaseong-si (KR)

(73) Assignee: SAMSUNG ELECTRONICS CO., LTD., Suwon-Si (KR)

(21) Appl. No.: 14/191,832

(22) Filed: Feb. 27, 2014

(30) Foreign Application Priority Data
Mar. 15, 2013 (KR) 10-2013-0027643

(51) Int. Cl. H01L 29/78; H01L 29/51; H01L 21/28

(52) U.S. Cl. CPC H01L 29/7827; H01L 21/28158; H01L 29/518; H01L 29/511
USPC 257/330; 438/589

(57) ABSTRACT

In a method of manufacturing a semiconductor device, a trench is formed by removing an upper portion of a substrate. A gate insulation layer pattern is formed on an inner wall of the trench. A gate electrode is formed on the gate insulation layer pattern. The gate electrode fills a lower portion of the trench. A capping layer is formed on the gate electrode and the gate insulation layer pattern. The capping layer is partially oxidized to form a first capping layer pattern and a second capping layer pattern. The first capping layer pattern is not oxidized, and the second capping layer pattern is oxidized. A third capping layer pattern is formed on the second capping layer pattern, the third capping layer pattern filling an upper portion of the trench.

### CROSS REFERENCE TO RELATED APPLICATION

This application claims priority under 35 USC §119 to Korean Patent Application No. 2013-0027643, filed on Mar. 15, 2013 in the Korean Intellectual Property Office (KIPO), the contents of which are herein incorporated by reference in their entirety.

### BACKGROUND

1. Field

Example embodiments relate to semiconductor devices and/or methods of manufacturing the semiconductor devices.

2. Description of the Related Art

Recently, as the integration degree of a semiconductor device, e.g., a DRAM device, increases, a length of a channel decreases, and a short channel effect or a source/drain punch-through effect occurs. Therefore, a leakage current becomes a problem. In order to solve the problem, a recess channel array transistor having a gate electrode partially buried on a substrate is suggested. However, at a region where a gate electrode and a drain region are overlapped, a gate induced drain leakage (GIDL) current may occur.

### SUMMARY

Example embodiments provide a semiconductor device capable of reducing a leakage current.

Example embodiments provide a method of manufacturing a semiconductor device capable of reducing a leakage current.

According to example embodiments, there is provided a method of manufacturing a semiconductor device. In the method, a trench is formed by removing an upper portion of a substrate. A gate insulation layer pattern is formed on an inner wall of the trench. A gate electrode is formed on the gate insulation layer pattern. The gate electrode fills a lower portion of the trench. A capping layer is formed on the gate electrode and the gate insulation layer pattern. The capping layer is partially oxidized to form a first capping layer pattern and a second capping layer pattern. The first capping layer pattern is not oxidized, and the second capping layer pattern is oxidized. A third capping layer pattern is formed on the second capping layer pattern, the third capping layer pattern filling an upper portion of the trench.

In example embodiments, the capping layer may be formed by a deposition process using silicon nitride.

In example embodiments, the capping layer may be partially oxidized by performing a thermal oxidation process in an atmosphere including an oxygen gas at a temperature of about 300° C. to about 600° C.

In example embodiments, the capping layer may be formed to have a first portion directly contacting the gate insulation layer pattern and a second portion directly contacting the gate electrode, and the capping layer may be partially oxidized by oxidizing the first portion of the capping layer and partially oxidizing the second portion of the capping layer.

In example embodiments, the capping layer may be formed to have a first portion directly contacting the gate insulation layer pattern and a second portion directly contacting the gate electrode, and the capping layer may be partially oxidized by partially oxidizing the first portion of the capping layer and partially oxidizing the second portion of the capping layer.

In example embodiments, the third capping layer pattern may be formed by a deposition process using silicon nitride.

According to example embodiments, there is provided a method of manufacturing a semiconductor device. In the method, a trench is formed by removing an upper portion of a substrate. A gate insulation layer pattern is formed on an inner wall of the trench. A gate electrode is formed on the gate insulation layer pattern. The gate electrode fills a lower portion of the trench. A first capping layer pattern is formed on the gate electrode and the gate insulation layer pattern. A second capping layer pattern is formed on the first capping layer pattern. A third capping layer pattern is formed on the second capping layer pattern. The third capping layer pattern fills an upper portion of the trench.

In example embodiments, the first capping layer pattern may be formed by a deposition process using silicon nitride.

In example embodiments, the second capping layer pattern may be formed by forming a preliminary second capping layer pattern including one of silicon oxide and silicon oxynitride, and thermally oxidizing the preliminary second capping layer pattern.

According to example embodiments, there is provided a semiconductor device including a substrate, an impurity region, a gate insulation layer pattern, a first capping layer pattern, a second capping layer pattern and a third capping layer pattern. The substrate includes a trench thereon. The impurity region is at an upper portion of the substrate adjacent to the trench. The gate insulation layer pattern is on an inner wall of the trench. The gate electrode is on the gate insulation layer pattern. The gate electrode fills a lower portion of the trench. A first capping layer pattern is on the gate electrode. The second capping layer pattern is on the first capping layer pattern and the gate insulation layer pattern. The second capping layer pattern includes a material different from that of the first capping layer pattern. The third capping layer pattern is on the second capping layer pattern. The third capping layer pattern fills an upper portion of the trench.

In example embodiments, the first capping layer pattern and the third capping layer pattern may include silicon nitride, and the second capping layer pattern may include silicon oxynitride.

In example embodiments, the first capping layer pattern, the second capping layer pattern and the third capping layer pattern may include positive charges.

In example embodiments, the second capping layer pattern and the gate electrode may be separated by the first capping layer pattern.

In example embodiments, the first capping layer pattern may be between a top surface of the gate electrode and a bottom surface of the second capping layer pattern.

In example embodiments, the first capping layer pattern may be between the gate insulation layer pattern and the second capping layer pattern.

According to example embodiments, there is provided a method of manufacturing a semiconductor device. A trench is formed by removing an upper portion of a substrate. A gate insulation layer pattern is formed on an inner wall of the trench. A gate electrode is formed on the gate insulation layer pattern, and the gate electrode fills a lower portion of the trench. A first capping layer pattern is formed on the gate electrode and the gate insulation layer pattern, and the first capping layer pattern includes a first material. A second capping layer pattern is formed on the first capping layer pattern, and the second capping layer pattern includes a second material different from the first material. A third capping layer pattern is formed on the second capping layer pattern, the third capping layer pattern filling an upper portion of the trench.

In example embodiments, the first capping layer pattern may be formed of silicon nitride, and the second capping layer pattern may be formed of silicon oxynitride.

In example embodiments, the third capping layer may be formed of the first material.

In example embodiments, the second capping layer pattern may be formed to be separated from the gate electrode by the first capping layer pattern.

In example embodiments, the first capping layer pattern may be formed on a top surface of the gate electrode, and the second capping layer pattern may be formed on a top surface of the first capping layer pattern.

In example embodiments, the second capping layer pattern may be formed to be separated from the gate insulation layer pattern by the first capping layer pattern.

According to example embodiments, a semiconductor device may include a capping layer structure including a second capping layer pattern formed by a thermal oxidation process about a first capping layer pattern. The capping layer structure, particularly the second capping layer pattern, may be formed without using the plasma treatment process, so that the interfacial trap having the negative charge may not be formed in the capping layer structure. That is, the capping layer structure in accordance with example embodiments may have more positive charges compared to the capping layer structure formed by the plasma treatment process. The positive charge included in the capping layer structure may reduce a gate-induced-drain-leakage (GIDL) current.

### BRIEF DESCRIPTION OF THE DRAWINGS

Example embodiments will be more clearly understood from the following detailed description taken in conjunction with the accompanying drawings. FIGS. 1 to 22 represent non-limiting, example embodiments as described herein.

FIG. 1 is a cross-sectional view illustrating a semiconductor device in accordance with example embodiments;

FIGS. 2 to 8 are cross-sectional views illustrating a method of manufacturing a semiconductor device in accordance with example embodiments;

FIG. 9 is a graph showing capacitance-voltage characteristics in accordance with example embodiments and a comparative example.

FIG. 10 is a cross-sectional view illustrating a semiconductor device in accordance with example embodiments;

FIGS. 11 to 13 are cross-sectional views illustrating a method of manufacturing a semiconductor device in accordance with example embodiments;

FIGS. 14 to 16 are cross-sectional views illustrating a method of manufacturing a semiconductor device in accordance with example embodiments;

FIGS. 17 to 21 are cross-sectional views illustrating a method of manufacturing a semiconductor device in accordance with example embodiments; and

FIG. 22 is a block diagram illustrating a system including the semiconductor device.

### DETAILED DESCRIPTION

Various example embodiments will be described more fully hereinafter with reference to the accompanying drawings, in which example embodiments are shown. The present inventive concepts may, however, be embodied in many different forms and should not be construed as limited to the example embodiments set forth herein. Rather, these example embodiments are provided so that this description will be thorough and complete, and will fully convey the scope of the present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

FIG. 1 is a cross-sectional view illustrating a semiconductor device in accordance with example embodiments.

Referring to FIG. 1, the semiconductor device may include a gate insulation layer pattern 140, a gate electrode 145 and a capping layer structure 182 which may be disposed at an upper portion of a substrate 100. Further, the semiconductor device may further include an impurity region 105 disposed at the upper portion of the substrate 100 adjacent to the capping layer structure 182.

The substrate 100 may include a semiconductor substrate, e.g., a silicon substrate, germanium substrate or a silicon-germanium substrate, a silicon-on-insulator (SOI) substrate or a germanium-on-insulator (GOI) substrate.

An isolation layer 110 may be disposed at the upper portion of the substrate 100. The isolation layer 110 may include an insulation material, e.g., silicon oxide. The substrate 100 may be divided into a field region where the isolation layer 110 is disposed and the active region where the isolation layer 110 is not disposed.

A trench 130 may be disposed to overlap the active region of the substrate 100. In example embodiments, at least one trench 130 may be disposed to overlap a single active region. Therefore, the active region of the substrate 100 may be separated by the trench 130.

The gate insulation layer pattern 140 having a uniform thickness may be disposed on an inner wall of the trench 130. In example embodiments, the gate insulation layer pattern 140 may include silicon oxide or a metal oxide, and may have a uniform thickness.

The gate electrode 145 may be disposed on the gate insulation layer 140. The gate electrode 145 may fill a lower portion of the trench 130. In example embodiments, the gate electrode 145 may include a doped polysilicon, a metal or a metal nitride.

The capping layer structure 182 may be disposed on the gate electrode 145 to fill an upper portion of the trench 130. The capping layer structure 182 may include a plurality of capping layer patterns having different materials. In example embodiments, the capping layer structure 182 may include a first capping layer pattern 152, a second capping layer pattern 162 and a third capping layer pattern 172 which may be stacked sequentially.

The first capping layer pattern 152 may be disposed on the gate electrode 145. In example embodiments, the first capping layer pattern 152 may include silicon nitride. That is, the first capping layer pattern 152 may not substantially include an oxygen atom, and may consist essentially of silicon nitride. Further, the first capping layer pattern 152 may be disposed between the second capping layer pattern 162 and the gate electrode 145. Therefore, the first capping layer pattern 152 may prevent or reduce the gate electrode 145 from being oxidized by the second capping layer pattern 154. That is, the first capping layer pattern 152 may serve as a chemical barrier layer, such that the gate electrode 145 may maintain a relatively low electrical resistance without an oxidation thereof.

The second capping layer pattern 162 may be disposed on the first capping layer pattern 152 and a sidewall of the trench 130. For example, the second capping layer pattern 162 may include silicon oxynitride or silicon oxide. In example embodiments, the second capping layer pattern 162 may be formed by a thermal oxidation process about a silicon nitride layer in an atmosphere including an oxygen gas. The first capping layer pattern 152 and the second capping layer pattern 162 formed by the thermal oxidation process may include more positive charges compared to a silicon nitride layer and a silicon oxide layer formed by a plasma treatment process. That is, the silicon nitride layer and the silicon oxide layer formed by the plasma treatment process may include an interfacial trap having negative charges, so that the silicon nitride layer and the silicon oxide layer formed by the plasma treatment process may include less positive charges compared to the first capping layer pattern 152 and the second capping layer pattern 162 formed by the thermal oxidation process. The experimental results may be described with reference to FIG. 9 as follow.

Further, the second capping layer pattern 162 may directly contact the gate insulation layer pattern 140. In example embodiments, the second capping layer pattern 162 including silicon oxynitrideor silicon oxide may be disposed between the gate insulation layer pattern 140 including silicon oxide and the third capping layer pattern 172 including silicon nitride. Therefore, the second capping layer pattern 162 may relieve a stress between the gate insulation layer pattern 140 and the third capping layer pattern 172.

The third capping layer pattern 172 may be disposed on the second capping layer pattern 162 to fill a remaining portion of the trench 130. In example embodiments, the third capping layer pattern 172 may include silicon nitride. A sidewall and a bottom surface of the third capping layer pattern 172 may be surrounded by the second capping layer pattern 162.

The impurity region 105 may be disposed at the upper portion of the substrate 100 adjacent to the capping layer structure 182. The impurity region 105 may include n-type impurities or p-type impurities, and may have a relative high conductivity compared to a remaining portion of the substrate 100. In example embodiments, a bottom surface of the impurity region 105 may be disposed lower than a top surface of the gate electrode 145. Further, the impurity region 105 may have an impurity concentration above about 1×10¹⁵/cm³.

Therefore, the gate insulation layer pattern 140, the gate electrode 145, the capping layer structure 182 and the impurity region 105 may constitute a transistor. In example embodiments, the transistor may be a buried channel array transistor including the gate electrode 145 that may be buried at the upper portion of the substrate 100. Further, the impurity region 105 may serve as a source region or a drain region of the transistor.

According to example embodiments, the semiconductor device may include the capping layer structure 182 including the second capping layer pattern 162 formed by a thermal oxidation process about the silicon nitride layer. The capping layer structure 182, particularly the second capping layer pattern 162, may be formed without using the plasma treatment process, so that the interfacial trap having the negative charge may not be formed in the capping layer structure 182. That is, the capping layer structure 182 in accordance with example embodiments may have more positive charges compared to the capping layer structure formed by the plasma treatment process.

The positive charge included in the capping layer structure 182 may reduce a gate-induced-drain-leakage (GIDL) current. The GIDL current means a current flowing from the gate electrode 145 to the impurity region 105 serving the drain region, when the transistor is off. When the GIDL current increases, the transistor may not function as a switching device. According to example embodiments, the capping layer structure 182 having positive charges may be disposed on a migration route of the GIDL current, so that the GIDL current may be reduced or prevented.

FIGS. 2 to 8 are cross-sectional views illustrating a method of manufacturing a semiconductor device in accordance with example embodiments.

Referring to FIG. 2, impurities may be doped at an upper portion of a substrate 100 to form an impurity region 105, and an isolation layer 110 may be formed at the upper portion of the substrate 100.

The substrate 100 may include a semiconductor substrate, e.g., a silicon substrate, germanium substrate or a silicon-germanium substrate, a silicon-on-insulator (SOI) substrate or a germanium-on-insulator (GOI) substrate.

The impurity region 105 may be formed by doping n-type impurities or p-type impurities into the substrate 100. Therefore, the impurity region 105 may have a higher conductivity compared to a remaining region of the substrate 100.

The isolation layer 110 may be formed using silicon oxide by a shallow trench isolation (STI) process. Therefore, the substrate 100 may be divided into a field region where the isolation layer 110 is disposed and the active region where the isolation layer 110 is not disposed. In example embodiments, a plurality of active regions may be arranged in a first direction. Each of the active regions may extend in a second direction perpendicular to the first direction or a direction oriented obliquely to the second direction.

Referring to FIG. 3, after forming a mask 120 on the substrate 100 and the isolation layer 110, a trench 130 may be formed by partially removing the substrate 100 and the isolation layer 110.

The mask 120 may be formed by forming a mask layer and a photoresist pattern on the substrate 100 and the isolation layer 110, and by patterning the mask layer using the photoresist pattern. For example, the mask layer may be formed using silicon nitride by a chemical vapor deposition (CVD) process, a low pressure chemical vapor deposition (LPCVD) process, a plasma enhanced chemical vapor deposition (PECVD) process or a spin coating process.

In example embodiments, a plurality of masks 120 may be arranged in the second direction. Each of the masks 120 may extend in the first direction.

The trench 130 may be formed by performing an etching process using the mask 120 as an etching mask. For example, the etching process may include a dry etching process or a reactive ion etching (RIE) process.

In example embodiments, at least one trench 130 may overlap the active region of the substrate 100. As illustrated in FIG. 3, a couple of trenches 130 may overlap a single active region of the substrate 100. Therefore, impurity regions 105 of the substrate 100 may be separated by the trench 130.

Referring to FIG. 4, a gate insulation layer pattern 140 and a gate electrode 145 may be formed to partially fill the trench 130.

In an example embodiment, the gate insulation layer pattern 140 may be formed by thermally oxidizing a top surface and a sidewall of the substrate 100 exposed by the trench 130. Therefore, the gate insulation layer pattern 140 having a uniform thickness may be disposed on an inner wall of the trench 130. The gate insulation layer pattern 140 may include silicon oxide. A gate electrode layer may be formed on the gate insulation layer pattern 140 and the mask 120 to fill the trench 130, and an upper portion of the gate electrode layer may be removed by a chemical mechanical polishing process and/or an etch back process, thereby forming the gate electrode 145. For example, the gate electrode layer may be formed using a doped polysilicon, a metal or a metal nitride using a physical vapor deposition (PVD) process, an atomic layer deposition (ALD) process or a sputtering process.

In example embodiments, the gate insulation layer pattern 140 and the gate electrode 145 may be formed by forming a gate insulation layer and a gate electrode layer filling the trench 130 sequentially, and by removing upper portions of the gate insulation layer and the gate electrode layer by a CMP process or an etch back process. In example embodiments, the gate insulation layer may be formed using silicon oxide or a metal oxide by a CVD process or an ALD process.

Referring to FIG. 5, a first capping layer 150 may be formed on the mask 120, the gate insulation layer pattern 140 and the gate electrode 145.

The first capping layer 150 may be formed using silicon nitride by an ALD process or a CVD process. In example embodiments, the first capping layer 150 may have a varying thickness. For example, the first capping layer 150 may include a first portion contacting the gate insulation layer pattern 140 and a second portion contacting the gate electrode 145. In example embodiments, a thickness of the first portion of the first capping layer 150 may be substantially smaller than a thickness of the second portion of the first capping layer 150.

Referring to FIG. 6, a first capping layer pattern 152 and the second capping layer 160 may be formed by performing a thermal oxidation process about the first capping layer 150.

The thermal oxidation process may be performed in an atmosphere including an oxygen gas and an inert gas at a temperature of about 300° C. to about 600° C. Therefore, the first capping layer 150 including silicon nitride may be partially oxidized to form the second capping layer 160 including silicon oxynitride. However, the period and the temperature of the thermal oxidation process may be adjusted, such that the first capping layer 150 may be partially oxidized. That is, the first portion of the first capping layer 150 contacting the gate insulation layer pattern 140 may be sufficiently oxidized, and the second portion of the first capping layer 150 contacting the gate electrode 145 may be partially oxidized. Therefore, a remaining portion of the first capping layer 150, that is not oxidized, may be defined as the first capping layer pattern 152.

The second capping layer 160 and the gate electrode 145 may be separated by the first capping layer pattern 152. That is, the second capping layer 160 may not directly contact the gate electrode 145, so that the first capping layer pattern 152 may prevent or reduce the gate electrode 145 from being oxidized by the second capping layer 160. Therefore, the gate electrode 145 may maintain a relatively low electrical resistance without an oxidation thereof.

According to example embodiments, the first capping layer pattern 152 and the second capping layer 160 formed by the thermal oxidation process may include more positive charges compared to a silicon nitride layer and a silicon oxide layer formed by a plasma treatment process. That is, the silicon nitride layer and the silicon oxide layer formed by the plasma treatment process may include an interfacial trap having negative charges, so that the silicon nitride layer and the silicon oxide layer formed by the plasma treatment process may include less positive charges compared to the first capping layer pattern 152 and the second capping layer pattern 162 formed by the thermal oxidation process. The experimental results may be described with reference to FIG. 9 as follow.

Referring to FIG. 7, a third capping layer 170 may be formed on the second capping layer 160 to fill the trench 130.

In example embodiments, the third capping layer 170 may be formed using silicon nitride by an ALD process or a CVD process. That is, the third capping layer 170 may fill a remaining portion of the trench 130.

Referring to FIG. 8, upper portions of the second capping layer 160 and the third capping layer 170 may be removed to form a second capping layer pattern 162 and the third capping layer pattern 172.

The upper portions of the second capping layer 160 and the third capping layer 170, and the mask 120 may be removed by performing a CMP process or an etch back process until a top surface of the substrate 100 is exposed. Therefore, the second capping layer pattern 162 and the third capping layer pattern 172 may be formed on the first capping layer pattern 152 to fill the upper portion of the trench 130.

Accordingly, a capping layer structure 182 may be formed to include the first capping layer pattern 152, the second capping layer pattern 162 and the third capping layer pattern 172.

According to example embodiments, the capping layer structure 182 may be formed to include the second capping layer pattern 162 formed by a thermal oxidation process about the first capping layer 150. The capping layer structure 182, particularly the second capping layer pattern 162, may be formed without using the plasma treatment process, so that the interfacial trap having the negative charge may not be formed in the capping layer structure 182. That is, the capping layer structure 182 in accordance with example embodiments may have more positive charges compared to the capping layer structure formed by the plasma treatment process. The positive charge included in the capping layer structure 182 may reduce a gate-induced-drain-leakage (GIDL) current.

FIG. 9 is a graph showing capacitance-voltage (C-V) characteristics of metal oxide semiconductor (MOS) structures in accordance with example embodiments and a comparative example. In the graph of FIG. 9, the horizontal X-axis may show values of input voltage applied to the MOS structure in volts (V), and the vertical Y-axis may show values of capacitance of the MOS structure.

In the graph of FIG. 9, notation I designates a graph of the capacitance-voltage characteristic of the MOS structure including a silicon nitride layer and a silicon oxynitride layer formed by a thermal oxidation according to example embodiments, and notation II designates a graph of the capacitance-voltage characteristic of the MOS structure a silicon nitride layer and a silicon oxynitride layer formed by a plasma treatment process according to a comparative example.

In example embodiments I, a silicon nitride layer may be formed to have a thickness of about 60 Å to about 80 Å on a silicon substrate. The silicon nitride layer may be partially oxidized by a thermal oxidation process to form a silicon oxynitride layer. A conductive metal layer (or a conductive metal nitride layer) may be formed on the silicon oxynitride layer, thereby forming the MOS structure.

In the comparative example II, a silicon oxide layer may be formed to have a thickness of about 60 Å to about 80 Å on a silicon substrate. The silicon oxide layer may be partially nitrided by a plasma treatment process to form a silicon oxynitride layer or a silicon nitride layer. A conductive metal layer (or a conductive metal nitride layer) may be formed on the silicon oxynitride layer, thereby forming the MOS structure.

Referring to FIG. 9, as the values of input voltage applied to the MOS structure increases, the capacitance of the MOS structure may vary, and the graph may be divided into an accumulation region, a depletion region and an inversion region. Particularly, in the depletion region, the capacitance of the MOS structure may decrease, as the input voltage increases. When comparing the depletion regions of the example embodiments I and the comparative example II, the depletion region of the example embodiments I may be shifted to the left in −0.3V compared to the depletion region of the comparative example II. Therefore, the MOS structure of the example embodiments I may include more positive charges compared to the MOS structure of the comparative example II.

FIG. 10 is a cross-sectional view illustrating a semiconductor device in accordance with example embodiments. The semiconductor device may be substantially the same as or similar to those illustrated with reference to FIG. 1. Thus, like reference numerals refer to like elements, and repetitive explanations thereon may be omitted herein.

Referring to FIG. 10, the semiconductor device may include a gate insulation layer pattern 140, a gate electrode 145 and a capping layer structure 184 which may be disposed at an upper portion of a substrate 100. Further, the semiconductor device may include an impurity region 105 disposed at the upper portion of the substrate 100 adjacent to the capping layer structure 184.

The substrate 100 may include a semiconductor substrate, e.g., a silicon substrate, germanium substrate or a silicon-germanium substrate, a silicon-on-insulator (SOI) substrate or a germanium-on-insulator (GOI) substrate. An isolation layer 110 may be disposed at the upper portion of the substrate 100.

A trench 130 may be disposed at the upper portion of the substrate 100. The gate insulation layer pattern 140 including silicon oxide or a metal oxide may be disposed on an inner wall of the trench 130. Further, the gate electrode 145 and the capping layer structure 184 may be disposed on the gate insulation layer 140 to fill the trench 130.

In example embodiments, the capping layer structure 184 may include a first capping layer pattern 154, a second capping layer pattern 164 and a third capping layer pattern 174 which may be stacked sequentially.

The first capping layer pattern 154 may be disposed on a top surface of the gate electrode 145 and a sidewall of the trench 130. In example embodiments, the first capping layer pattern 154 may be disposed not only between the second capping layer pattern 164 and the gate electrode 145, but also between the gate insulation layer pattern 140 and the second capping layer pattern 164. The first capping layer pattern 154 may include silicon nitride.

The second capping layer pattern 164 may be disposed on the first capping layer pattern 154. For example, the second capping layer pattern 164 may include a silicon oxynitride. In example embodiments, the second capping layer pattern 164 may be formed by a thermal oxidation process about a silicon nitride layer in an atmosphere including an oxygen gas. The first capping layer pattern 154 and the second capping layer pattern 164 formed by the thermal oxidation process may include more positive charges compared to a silicon nitride layer and a silicon oxide layer formed by a plasma treatment process.

The third capping layer pattern 174 may be disposed on the second capping layer pattern 164 to fill a remaining portion of the trench 130. For example, the third capping layer pattern 174 may include silicon nitride.

The impurity region 105 including n-type impurities or p-type impurities may be disposed at the upper portion of the substrate 100 adjacent to the capping layer structure 184. Therefore, the gate insulation layer pattern 140, the gate electrode 145, the capping layer structure 184 and the impurity region 105 may constitute a transistor.

According to example embodiments, the capping layer structure 184 may be formed to include the second capping layer pattern 164 formed by a thermal oxidation process about the first capping layer 150. The capping layer structure 184, particularly the second capping layer pattern 164, may be formed without using the plasma treatment process, so that the interfacial trap having the negative charge may not be formed in the capping layer structure 184. That is, the capping layer structure 184 in accordance with example embodiments may have more positive charges compared to the capping layer structure formed by the plasma treatment process. The positive charge included in the capping layer structure 184 may reduce a gate-induced-drain-leakage (GIDL) current.

FIGS. 11 to 13 are cross-sectional views illustrating a method of manufacturing a semiconductor device in accordance with example embodiments.

The method of manufacturing the wiring may be substantially the same as or similar to those illustrated with reference to FIGS. 2 to 8. Thus, like reference numerals refer to like elements, and repetitive explanations thereon may be omitted herein.

First, processes substantially the same as or similar to those illustrated with reference to FIGS. 2 to 4 may be performed. That is, impurities may be doped at an upper portion of a substrate 100 to form an impurity region 105, and an isolation layer 110 may be formed at the upper portion of the substrate 100. After forming a mask 120 on the substrate 100 and the isolation layer 110, a trench 130 may be formed by partially removing the substrate 100 and the isolation layer 110. A gate insulation layer pattern 140 and a gate electrode 145 may be formed to partially fill the trench 130.

Referring to FIG. 11, a first capping layer 150 may be formed on the mask 120, the gate insulation layer pattern 140 and the gate electrode 145.

The first capping layer 150 may be formed using silicon nitride by a CVD process or an ALD process. In example embodiments, the first capping layer 150 having a uniform thickness may be formed on the mask 120, the gate insulation layer pattern 140 and the gate electrode 145 by the ALD process.

Referring to FIG. 12, a second capping layer 160 may be formed by performing a thermal oxidation process about the first capping layer 150.

The thermal oxidation process may be performed in an atmosphere including an oxygen gas and an inert gas at a temperature of about 300° C. to about 600° C. Therefore, the first capping layer 150 may be disposed between the second capping layer 160 and the gate electrode 145, and may be disposed between the second capping layer 160 and the gate insulation layer pattern 140. The first capping layer 150 may prevent or reduce the second capping layer including silicon oxynitride from directly contacting the gate electrode 145.

Referring to FIG. 13, after forming a third capping layer 170 on the second capping layer filling a remaining portion of the trench 130, upper portions of the third capping layer 170, the second capping layer 160 and the first capping layer 150 and the mask 120 may be removed to form a first capping layer pattern 154, a second capping layer pattern 164 and a third capping layer pattern 174.

The third capping layer 170 may be formed using silicon nitride by an ALD process and a CVD process.

The upper portions of the third capping layer 170, the second capping layer 160 and the first capping layer 150, and the mask 120 may be removed by a CMP process or an etch back process, until a top surface of the substrate 100 is exposed.

Accordingly, a capping layer structure 184 may be formed to include the first capping layer pattern 154, the second capping layer pattern 164 and the third capping layer pattern 174.

According to example embodiments, the capping layer structure 184 may be formed to include the second capping layer pattern 164 formed by a thermal oxidation process about the first capping layer 150. The capping layer structure 184, particularly the second capping layer pattern 164, may be formed without using the plasma treatment process, so that the interfacial trap having the negative charge may not be formed in the capping layer structure 184. That is, the capping layer structure 184 in accordance with example embodiments may have more positive charges compared to the capping layer structure formed by the plasma treatment process. The positive charge included in the capping layer structure 184 may reduce a gate-induced-drain-leakage (GIDL) current.

FIGS. 14 to 16 are cross-sectional views illustrating a method of manufacturing a semiconductor device in accordance with example embodiments. The method of manufacturing the wiring may be substantially the same as or similar to those illustrated with reference to FIGS. 2 to 8. Thus, like reference numerals refer to like elements, and repetitive explanations thereon may be omitted herein.

First, processes substantially the same as or similar to those illustrated with reference to FIGS. 2 to 4 may be performed.

Referring to FIG. 14, a first capping layer 150 may be formed on the mask 120, the gate insulation layer pattern 140 and the gate electrode 145. The first capping layer 150 may be formed using silicon nitride by a CVD process or an ALD process.

Referring to FIG. 15, a second capping layer 160 may be formed on the first capping layer 150.

In example embodiments, the second capping layer 160 may be formed using silicon oxide by an ALD process or a CVD process. The second capping layer 160 having a uniform thickness may be formed on the first capping layer 150.

A heat treatment process may be performed about the second capping layer 160 at a temperature above about 300° C. Therefore, a nitrogen atom in the first capping layer 150 may diffuse into the second capping layer 160, so that the second capping layer 160 may include silicon oxynitride.

Referring to FIG. 16, after forming a third capping layer (not shown) on the second capping layer 160 filling a remaining portion of the trench 130, upper portions of the third capping layer (not shown), the second capping layer 160 and the first capping layer 150 and the mask 120 may be removed to form a first capping layer pattern 156, a second capping layer pattern 166 and a third capping layer pattern 176.

Accordingly, a capping layer structure 186 may be formed to include the first capping layer pattern 156, the second capping layer pattern 166 and the third capping layer pattern 176.

According to example embodiments, the capping layer structure 186 may be formed to include the second capping layer pattern 166 formed by a thermal oxidation process about the first capping layer 150. The capping layer structure 184, particularly the second capping layer pattern 166, may be formed without using the plasma treatment process, so that the interfacial trap having the negative charge may not be formed in the capping layer structure 186. That is, the capping layer structure 186 in accordance with example embodiments may have more positive charges compared to the capping layer structure formed by the plasma treatment process. The positive charge included in the capping layer structure 186 may reduce a gate-induced-drain-leakage (GIDL) current.

FIGS. 17 to 21 are cross-sectional views illustrating a method of manufacturing a semiconductor device in accordance with example embodiments. FIGS. 17 to 21 may include cross-sectional views illustrating a cell region III and cross-sectional views illustrating a peripheral region IV, respectively.

Referring to FIG. 17, an isolation layer 210 may be formed at an upper portion of a substrate 200, and a first impurity region 205 and a trench 230 may be formed in the cell region III of the substrate 200 after forming a mask 220 on the substrate 200 and the isolation layer 210. Processes for forming the first impurity region 205, the isolation layer 210 and the trench 230 may be substantially the same as or similar to those illustrated with reference to FIGS. 2 and 3.

Referring to FIG. 18, a first gate insulation layer pattern 240, a first gate electrode 245 and a capping layer structure 282 may be formed to fill the trench 230. Processes for forming the first gate insulation layer pattern 240, the first gate electrode 245 and the capping layer structure 282 may be substantially the same as or similar to those illustrated with reference to FIGS. 4 to 9. In example embodiments, the capping layer structure 282 may include a first capping layer pattern 252, a second capping layer pattern 262 and a third capping layer pattern 272 which may be stacked sequentially.

Referring to FIG. 19, an insulation layer 300 may be formed in the cell region III of the substrate 200, and a second impurity region 290 and a second gate structure 291 may be formed in the peripheral region IV on the substrate 200.

A second gate insulation layer, a second gate electrode layer and a second gate mask layer may be sequentially formed in the peripheral region IV on the substrate 200, and the second gate insulation layer, the second gate electrode layer and the second gate mask layer may be patterned to form the second gate structure 291 including a second gate insulation layer pattern 292, a second gate electrode 294 and a second mask 296. The second gate insulation layer pattern 292 may be formed using silicon oxide or a metal oxide. The second gate electrode 294 may be formed using a doped polysilicon or a metal. The second mask 296 may be formed using silicon nitride.

The second impurity region 290 may be formed implanting impurities into an upper portion of the substrate 200 in the peripheral region IV using the second gate structure 291 as an implantation mask. The second impurity region 290 may serve as a source region or a drain region of a transistor. Further, spacers 298 including silicon nitride may be formed on a sidewall of the gate structure 291.

Referring to FIG. 20, in the cell region III, a first insulating interlayer 310 and a first contact 315 penetrating the first insulating interlayer 310 may be formed on the substrate 200, and a bit line 320 and a second insulating interlayer 325 may be formed on the first insulating interlayer 325. A second contact 330 may be formed to penetrate the first insulating interlayer 310 and the second insulating inter layer 325.

The first insulating interlayer 310 may be formed on the substrate 200 and the insulation layer 300 to cover the second gate structure 291 and the second spacer 298.

The insulation layer 300 and the first insulating interlayer 310 may be partially removed to form a first contact hole exposing the first impurity region 205. A first contact layer may be formed on the first insulating interlayer 310 to fill the first contact hole, and an upper portion of the first contact layer may be planarized by a CMP process or an etch back process until a top surface of the first insulating interlayer 310 is exposed, such that the first contact 315 may be formed in the first contact hole. The first contact 315 may be electrically connected to the first impurity region 205. The first contact layer may be formed using a doped polysilicon, a conductive metal or a conductive metal nitride. The first contact 315 may sever as a bit line contact.

A bit line layer may be formed on the first contact 315 and the first insulating interlayer 310, and the bit line layer may be patterned to form the bit line 320. The bit line layer may be formed using a doped polysilicon, a conductive metal or a conductive metal nitride. A bit line mask and a bit line spacer may be further formed on a top surface and a sidewall of the bit line 320 to protect the bit line 320.

A second insulating interlayer 325 may be formed on the first insulating interlayer 310 to cover the bit line 320.

The first insulating interlayer 310 and the second insulating interlayer 325 may be partially removed to form a second contact hole exposing the first impurity region 205. A second contact layer may be formed on the second insulating interlayer 325 to fill the second contact hole, and an upper portion of the second contact layer may be planarized by a CMP process or an etch back process until a top surface of the second insulating interlayer 325 is exposed, such that the second contact 330 may be formed in the second contact hole. The second contact 330 may be electrically connected to the first impurity region 205. The second contact 330 may sever as a capacitor contact.

Referring to FIG. 21, after forming a capacitor 360 electrically connected to the second contact 330 in the cell region III, a third contact 370 and a conductive line 372 may be formed in the peripheral region IV.

In the cell region III, a lower electrode 362, a dielectric layer 364 and an upper electrode 366 may be sequentially formed, such that the capacitor 360 may be defined.

An etch stop layer 340 and a third insulating interlayer 350 may be formed on the second insulating interlayer 325 and the second contact 330, and portions of the etch stop layer 340 and the third insulating interlayer 350 may be removed to form an opening exposing the second contact 330. A lower electrode layer may be formed on an inner wall of the opening and the third insulating interlayer 350, and an upper portion of the lower electrode layer may be removed to form the lower electrode 362. The third insulating interlayer 350 in the cell region may be removed by an etching process.

The dielectric layer 364 may be formed on the lower electrode 362 and the etch stop layer 340 using a relatively high dielectric material having a dielectric constant higher than that of silicon oxide or silicon nitride. For example, the high dielectric material may include tantalum oxide, hafnium oxide, aluminum oxide, and/or zirconium oxide. The relatively high dielectric material may be used alone, or may be used as a mixture thereof.

The upper electrode 366 may be formed using a metal, a metal nitride or doped polysilicon by a CVD process, a PVD process, and/or an ALD process. The upper electrode 366 may be a cylinder type or may be a thin film type.

In the peripheral region IV, the third contact 370 and the conductive line 372 may be formed.

The third insulating interlayer 350, the second insulating interlayer 325 and the first insulating interlayer 310 may be partially removed to form a third contact hole exposing the second impurity region 290. A third contact layer may be formed on the third insulating interlayer 350 to fill the third contact hole, and an upper portion of the third contact layer may be planarized by a CMP process or an etch back process until a top surface of the third insulating interlayer 350 is exposed, such that the third contact 370 may be formed in the third contact hole.

According to example embodiment, the capping layer structure 282 may include more positive charges that may reduce a gate-induced-drain-leakage (GIDL) current.

FIG. 22 is a block diagram illustrating a system including the semiconductor device.

Referring to FIG. 22, a system 400 may include a memory 410, a memory controller 420 controlling the operation of the memory 410, a display part 430 outputting information, an interface 440 receiving information and a main processor 450 controlling the above described parts. The memory 410 may be a semiconductor device in accordance with example embodiments. The memory 410 may be directly connected to the main processor 450 or through a bus. The system 400 may be applied to a computer, a portable computer, a laptop computer, a personal portable terminal, a tablet, a cellular phone, and/or a digital music player.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as example embodiments, are intended to be included within the scope of the appended claims.

What is claimed is:

1. A method of manufacturing a semiconductor device, the method comprising:
forming a trench by removing an upper portion of a substrate;
forming a gate insulation layer pattern on an inner wall of the trench;
forming a gate electrode on the gate insulation layer pattern, the gate electrode filling a lower portion of the trench;
forming a capping layer on the gate electrode and the gate insulation layer pattern;
partially oxidizing the capping layer to form a first capping layer pattern and a second capping layer pattern, the first capping layer pattern not being oxidized and the second capping layer pattern being oxidized; and
forming a third capping layer pattern on the second capping layer pattern, the third capping layer pattern filling an upper portion of the trench.

2. The method of claim 1, wherein the forming a capping layer includes a deposition process using silicon nitride.

3. The method of claim 1, wherein the partially oxidizing the capping layer includes performing a thermal oxidation process in an atmosphere including an oxygen gas at a temperature of about 300° C. to about 600° C.

4. The method of claim 1, wherein
the forming a capping layer forms a first portion directly contacting the gate insulation layer pattern and a second portion directly contacting the gate electrode, and
the partially oxidizing the capping layer includes oxidizing the first portion of the capping layer and partially oxidizing the second portion of the capping layer.

5. The method of claim 1, wherein
the forming a capping layer forms a first portion directly contacting the gate insulation layer pattern and a second portion directly contacting the gate electrode, and
the partially oxidizing the capping layer includes partially oxidizing the first portion of the capping layer and partially oxidizing the second portion of the capping layer.

6. The method of claim 1, wherein the forming a third capping layer pattern includes a deposition process using silicon nitride.

7. A method of manufacturing a semiconductor device, the method comprising:
forming a trench by removing an upper portion of a substrate;
forming a gate insulation layer pattern on an inner wall of the trench;
forming a gate electrode on the gate insulation layer pattern, the gate electrode filling a lower portion of the trench;
forming a first capping layer pattern on the gate electrode and the gate insulation layer pattern;
forming a second capping layer pattern on the first capping layer pattern; and
forming a third capping layer pattern on the second capping layer pattern, the third capping layer pattern filling an upper portion of the trench.

8. The method of claim 7, wherein the forming a first capping layer pattern includes a deposition process using silicon nitride.

9. The method of claim 8, wherein the forming a second capping layer pattern comprises:
forming a preliminary second capping layer pattern including one of silicon oxide and silicon oxynitride; and
thermally oxidizing the preliminary second capping layer pattern.

10. A semiconductor device, comprising:
a substrate including a trench therein;
an impurity region at an upper portion of the substrate adjacent to the trench;
a gate insulation layer pattern on an inner wall of the trench;
a gate electrode on the gate insulation layer pattern, the gate electrode filling a lower portion of the trench;
a first capping layer pattern on the gate electrode;
a second capping layer pattern on the first capping layer pattern and the gate insulation layer pattern, the second capping layer pattern including a material different from that of the first capping layer pattern; and
a third capping layer pattern on the second capping layer pattern, the third capping layer pattern filling an upper portion of the trench.

11. The semiconductor device of claim 10, wherein
the first capping layer pattern and the third capping layer pattern include silicon nitride, and
the second capping layer pattern includes silicon oxynitride.

12. The semiconductor device of claim 10, wherein the first capping layer pattern, the second capping layer pattern and the third capping layer pattern include positive charges.

13. The semiconductor device of claim 10, wherein the second capping layer pattern and the gate electrode are separated by the first capping layer pattern.

14. The semiconductor device of claim 10, wherein the first capping layer pattern is between a top surface of the gate electrode and a bottom surface of the second capping layer pattern.

15. The semiconductor device of claim 14, wherein the first capping layer pattern is between the gate insulation layer pattern and the second capping layer pattern.

16. A method of manufacturing a semiconductor device, the method comprising:
forming a trench by removing an upper portion of a substrate;
forming a gate insulation layer pattern on an inner wall of the trench;
forming a gate electrode on the gate insulation layer pattern, the gate electrode filling a lower portion of the trench;
forming a first capping layer pattern on the gate electrode and the gate insulation layer pattern, the first capping layer pattern including a first material;
forming a second capping layer pattern on the first capping layer pattern, the second capping layer pattern including a second material different from the first material; and
forming a third capping layer pattern on the second capping layer pattern, the third capping layer pattern filling an upper portion of the trench.

17. The method of claim 16, wherein
the forming a first capping layer pattern forms silicon nitride, and
the forming a second capping layer pattern forms silicon oxynitride.

18. The method of claim 16, wherein the forming a third capping layer forms the first material.

19. The method of claim 16, wherein the forming a second capping layer pattern forms the second capping layer pattern separated from the gate electrode by the first capping layer pattern.

20. The method of claim 16, wherein
the forming a first capping layer pattern forms the first capping layer pattern on a top surface of the gate electrode, and
the forming a second capping layer pattern forms the second capping layer pattern on a top surface of the first capping layer pattern.

21. The method of claim 20, wherein the forming a second capping layer pattern forms the second capping layer pattern separated from the gate insulation layer pattern by the first capping layer pattern.
